(19) United States
(12) Patent Application Publication
(10) Pub. No.: US 2012/0037937 A1
(43) Pub. Date: Feb. 16, 2012

(54) LED PACKAGE STRUCTURE AND METHOD OF MAKING THE SAME

(75) Inventors: BILY WANG, HSINCHU CITY (TW); SUNG-YI HSIAO, MIAOLI COUNTY (TW); JACK CHEN, MIAOLI COUNTY (TW)

(73) Assignee: HARVATEK CORPORATION, HSINCHU CITY (TW)

(21) Appl. No.: 12/987,296

(22) Filed: Jan. 10, 2011

(30) Foreign Application Priority Data
Aug. 16, 2010 (TW) 99127314

(51) Int. Cl. H01L 33/56

(52) U.S. Cl. 257/98; 438/27; 257/E33.073; 257/E33.059; 257/E33.066; 257/E33.075

(57) ABSTRACT

An LED package structure includes a substrate unit, a conductive unit, a heat-dissipating unit, a light-emitting unit and a package unit. The substrate unit includes an insulating substrate. The conductive unit includes two top conductive pads disposed on top surface of the insulating substrate, two bottom conductive pads disposed on bottom surface of the insulating substrate, and a plurality of penetrating conductive posts passing the insulating substrate. The two top conducive pads respectively electrically connect the two bottom conductive pads through the penetrating conductive posts. The heat-dissipating unit includes a top heat-dissipating block and a bottom heat-dissipating block respectively disposed on top and bottom surfaces of the insulating substrate. The light-emitting unit includes a light-emitting element on the top heat-dissipating block and electrically connected between the two top conductive pads. The package unit includes a package resin on the conductive unit and the heat-dissipating unit to cover the light-emitting element.

### BACKGROUND OF THE INVENTION

1. Field of the Invention

The instant disclosure relates to an LED package structure and a method of making the same, and more particularly, to an LED package structure for increasing heat-dissipating efficiency and a method of making the same.

2. Description of Related Art

The invention of the lamp greatly changed the style of building construction and the living style of human beings, allowing people to work during the night. Traditional lighting devices such as lamps that adopt incandescent bulbs, fluorescent bulbs, or power-saving bulbs have been generally well-developed and used intensively for indoor illumination.

However, these traditional lamps have the disadvantages of quick attenuation, high power consumption, high heat generation, short working life, high fragility, and being not recyclable when compared to the newly developed light-emitting diode (LED) devices. Thus, these traditional light bulbs are gradually phased out in favor of the new and more efficient high-powered LED devices.

### SUMMARY OF THE INVENTION

One particular aspect of the instant disclosure is to provide an LED package structure for increasing heat-dissipating efficiency.

Another particular aspect of the instant disclosure is to provide a method of making an LED package structure for increasing heat-dissipating efficiency.

To achieve the above-mentioned advantages, one embodiment of the instant disclosure provides an LED package structure, including: a substrate unit, a conductive unit, a heat-dissipating unit, a light-emitting unit and a package unit. The substrate unit includes at least one insulating substrate. The conductive unit includes at least two plate-shaped top conductive pads disposed on the top surface of the insulating substrate, at least two plate-shaped bottom conductive pads disposed on the bottom surface of the insulating substrate, and a plurality of penetrating conductive posts passing through the insulating substrate. The two top conducive pads are respectively electrically connected to the two bottom conductive pads through the penetrating conductive posts. The heat-dissipating unit includes at least one plate-shaped top heat-dissipating block disposed on the top surface of the insulating substrate and at least one plate-shaped bottom heat-dissipating block disposed on the bottom surface of the insulating substrate. The light-emitting unit includes at least one light-emitting element disposed on the top heat-dissipating block and electrically connected between the two top conductive pads. The package unit includes a package resin disposed on the conductive unit and the heat-dissipating unit to cover the light-emitting element.

To achieve the above-mentioned advantages, one embodiment of the instant disclosure provides a method of making an LED package structure, including the steps of: (a) providing a substrate module including a substrate unit, a conductive unit and a heat-dissipating unit; wherein the substrate unit includes at least one insulating substrate, the conductive unit includes at least two top conductive pads disposed on the top surface of the insulating substrate, at least two bottom conductive pads disposed on the bottom surface of the insulating substrate and a plurality of penetrating conductive posts passing through the insulating substrate, the two top conducive pads are respectively electrically connected to the two bottom conductive pads through the penetrating conductive posts, and the heat-dissipating unit includes at least one top heat-dissipating block disposed on the top surface of the insulating substrate and at least one bottom heat-dissipating block disposed on the bottom surface of the insulating substrate; (b) attaching at least one light-emitting element to the top heat-dissipating block through die-attaching glue; (c) solidifying the die-attaching glue to position the light-emitting element on the top heat-dissipating block; (d) cleaning the outer surface of the light-emitting element and the outer surface of the two top conductive pads by plasma; (e) electrically connecting the light-emitting element between the two top conductive pads; and then (f) forming a package resin to cover the light-emitting element.

Therefore, heat generated by the light-emitting element can be transmitted to external world through the top heat-dissipating block, the insulating substrate (or the penetrating heat-dissipating layers) and the bottom heat-dissipating block in sequence. In other words, the heat generated by the light-emitting element can be quickly transmitted from the top heat-dissipating block to the bottom heat-dissipating block through the insulating substrate or the penetrating heat-dissipating layers, thus the heat-dissipating efficiency of the instant disclosure can be increased effectively.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIGS. 1-1 and 1-2 shows a flow chart of the method for making an LED package structure according to the first, the fourth and the fifth embodiments;

FIG. 1A shows one perspective, schematic view of the substrate module of the LED package structure according to the first embodiment of the instant disclosure;

FIG. 1B shows one lateral, schematic view of the substrate module of the LED package structure according to the first embodiment of the instant disclosure;

FIG. 1C shows one perspective, schematic view of the light-emitting element electrically connected to the substrate module of the LED package structure according to the first embodiment of the instant disclosure;

FIG. 1D shows one perspective, schematic view of the LED package structure according to the first embodiment of the instant disclosure;

FIG. 1E shows one lateral, schematic view of the LED package structure according to the first embodiment of the instant disclosure;

FIG. 2 shows one lateral, schematic view of the LED package structure according to the second embodiment of the instant disclosure;

FIG. 3 shows one lateral, schematic view of the LED package structure according to the third embodiment of the instant disclosure;

FIG. 4 shows one lateral, schematic view of the LED package structure according to the fourth embodiment of the instant disclosure;

FIG. 5 shows one lateral, schematic view of the LED package structure according to the fifth embodiment of the instant disclosure; and

FIG. 6 shows one lateral, schematic view of the LED package structure according to the sixth embodiment of the instant disclosure.

### DETAILED DESCRIPTION OF THE PREFERRED EMBODIMENTS

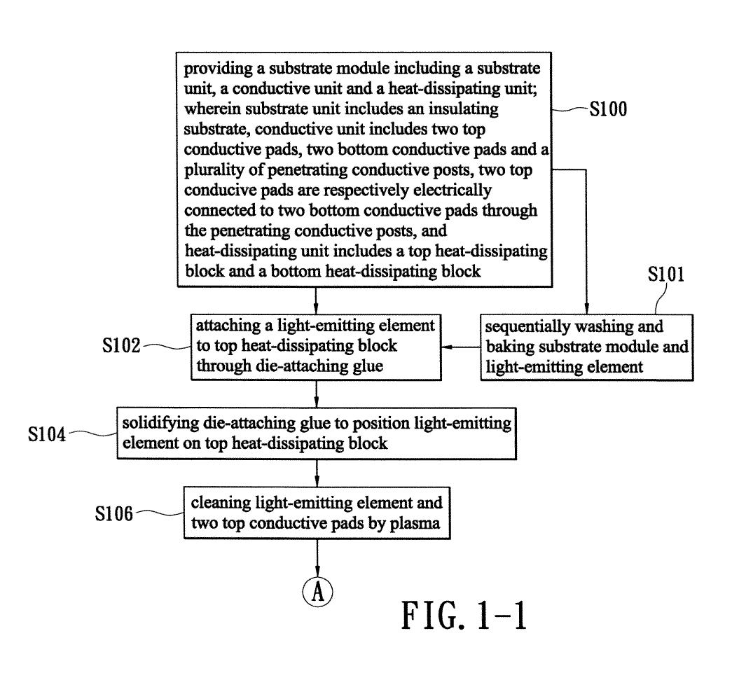

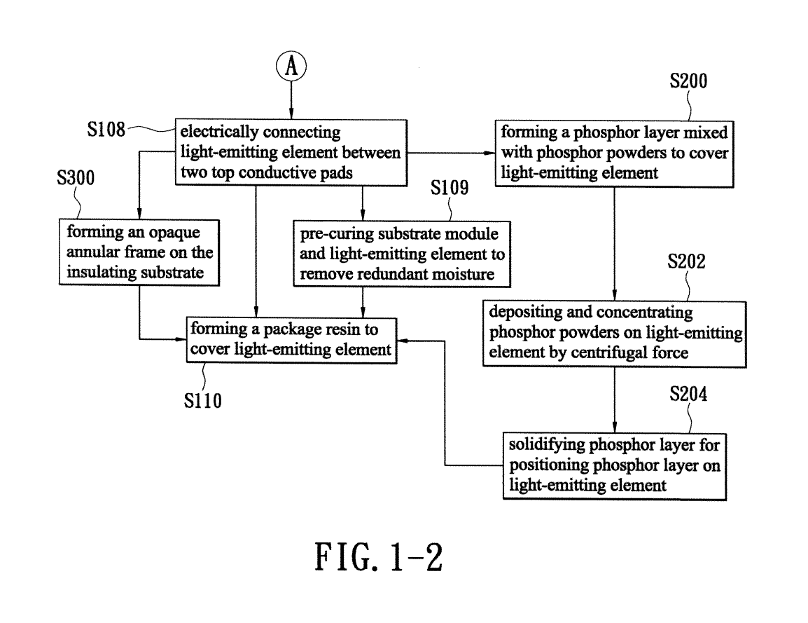

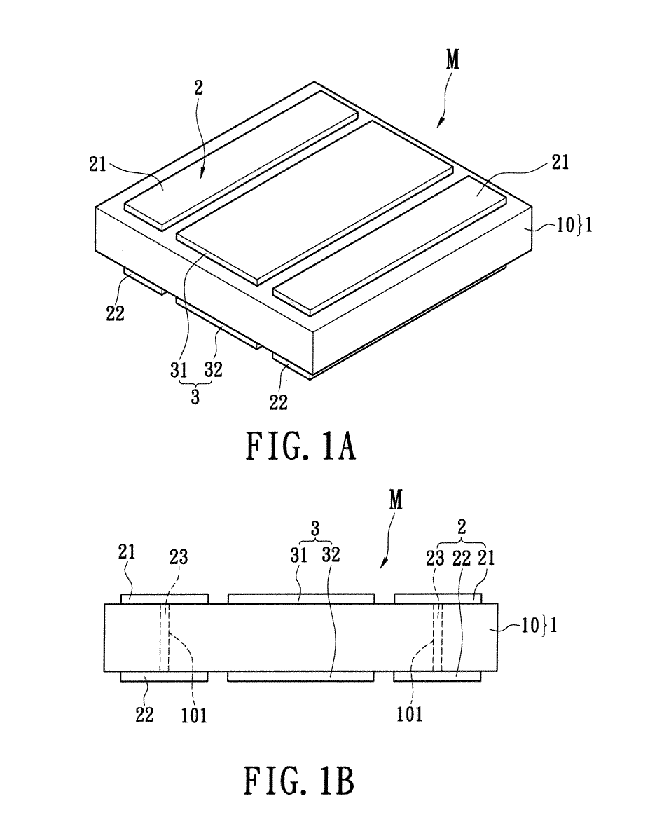

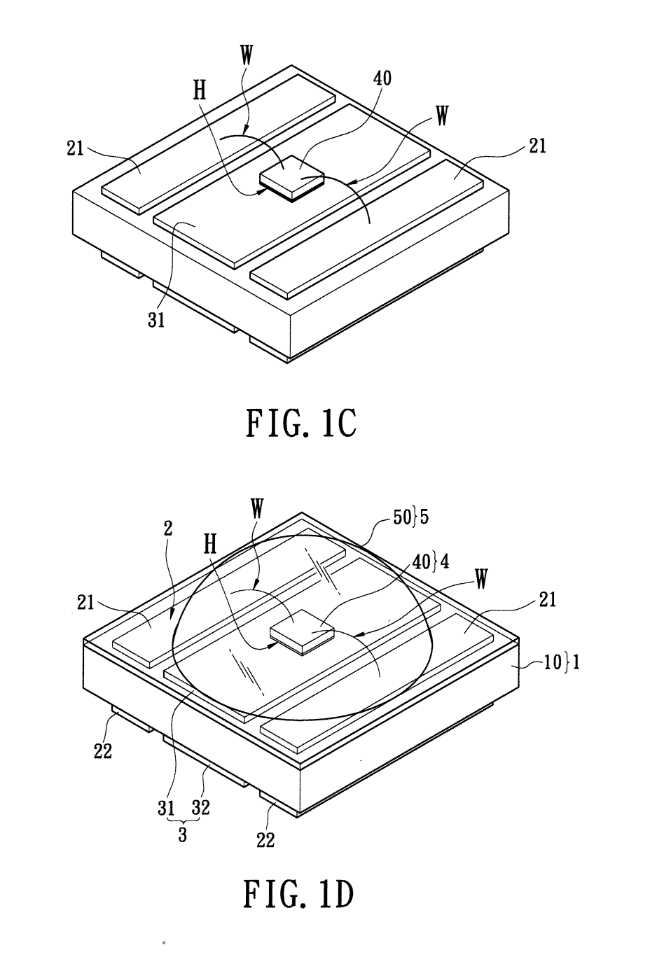

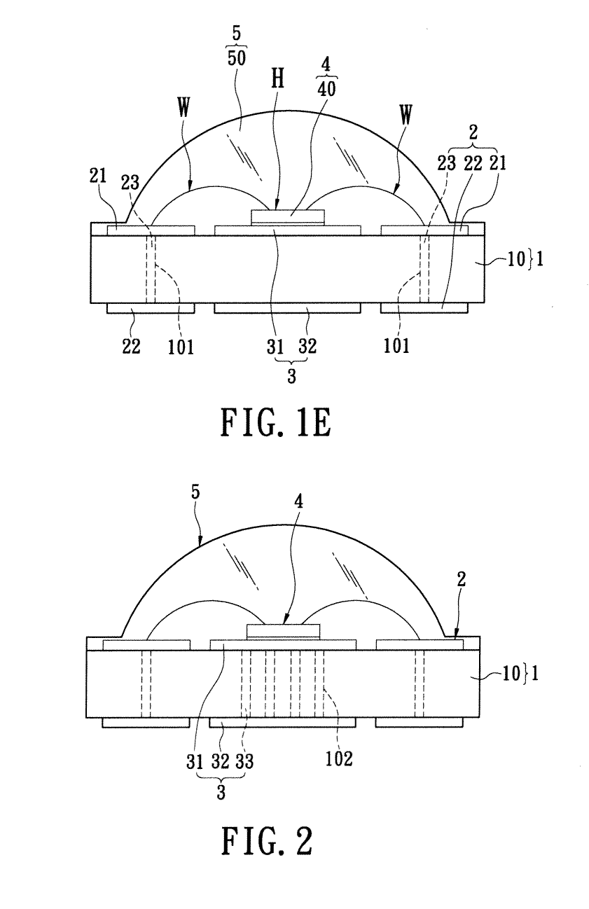

Referring to FIGS. 1-1, 1-2 and 1A-1E, the first embodiment of the instant disclosure provides a method of making an LED package structure for increasing heat-dissipating efficiency, comprising the steps of:

The step S100 is that: referring to FIGS. 1-1, 1-2, 1A and 1B (FIG. 1B shows a lateral view of FIG. 1A), providing a substrate module M including a substrate unit 1, a conductive unit 2 and a heat-dissipating unit 3; wherein the substrate unit 1 includes at least one insulating substrate 10, the conductive unit 2 includes at least two top conductive pads 21 disposed on the top surface of the insulating substrate 10, at least two bottom conductive pads 22 disposed on the bottom surface of the insulating substrate 10 and a plurality of penetrating conductive posts 23 passing through the insulating substrate 10, the two top conducive pads 21 are respectively electrically connected to the two bottom conductive pads 22 through the penetrating conductive posts 23, and the heat-dissipating unit 3 includes at least one top heat-dissipating block 31 disposed on the top surface of the insulating substrate 10 and at least one bottom heat-dissipating block 32 disposed on the bottom surface of the insulating substrate 10. In addition, the substrate unit 1 includes a plurality of conductive through holes 101 passing through the insulating substrate 10, and the penetrating conductive posts 23 are respectively filled in the conductive through holes 101.

The step S102 is that: referring to FIGS. 1-1, 1-2 and 1C, attaching at least one light-emitting element 40 to the top heat-dissipating block 31 through die-attaching glue (or die-attaching piece) H. For example, the light-emitting element 40 may be an LED chip. In addition, the method further comprises S101 that is sequentially washing and baking the substrate module M and the light-emitting element 40 before the step of S102 (washing the substrate module M and the light-emitting element 40, and then baking the substrate module M and the light-emitting element 40), and the temperature for the baking process may be between about 80-120° C.

The step S104 is that: referring to FIGS. 1-1, 1-2 and 1C, solidifying the die-attaching glue H to position the light-emitting element 40 on the top heat-dissipating block 31. For example, the temperature for the solidifying process may be between about 80-180° C., and the die-attaching glue H may be a conductive or non-conductive material, such as polymeric material, metal material or combing polymeric material and metal material.

The step S106 is that: referring to FIGS. 1-1, 1-2 and 1C, cleaning the outer surface of the light-emitting element 40 and the outer surface of the two top conductive pads 21 by plasma. For example, the power and the time for the plasma cleaning process may be 500 mW and between about 3-15 minutes, respectively.

The step S108 is that: referring to FIGS. 1-1, 1-2 and 1C, electrically connecting the light-emitting element 40 between the two top conductive pads 21. For example, the temperature and the bonding pressure for the electrically connecting process may be between about 100-230° C. and between about 10-150 gram, respectively. In addition, the positive electrode and the negative electrode of the light-emitting element 40 can respectively electrically connected to the two top conductive pads 21 through two conductive wires W. The method further comprising S109 that is pre-curing the substrate module M and the light-emitting element 40 to remove redundant moisture and increase the temperature for the electrically connecting process after the step of S108.

The step S110 is that: referring to FIGS. 1-1, 1-2, 1D and 1E (FIG. 1E shows a lateral view of FIG. 1D), forming a package resin 50 to cover the light-emitting element 40 to finish the manufacture of the LED package structure for increasing heat-dissipating efficiency of the instant disclosure. For example, the package resin 50 can be a light-permitting lens made of silicone or epoxy. In addition, the package resin 50 can be formed on the substrate module M (including the substrate unit 1, the conductive unit 2 and heat-dissipating unit 3) through a mold by molding method, and the temperature for the molding process is between about 50-180° C.

Moreover, the method may further comprise sawing, testing and sorting, and taping in sequence. For example, many LED package structures can be manufactured at the same time, and the LED package structures can be cut to form many strip LED package structures by sawing process. In addition, every strip LED package structure needs to be tested and sorted (GO or NG) by testing and sorting process, and then every normal strip LED package structure is rolled up by taping process.

Hence, referring to FIGS. 1D and 1E, the first embodiment of the instant disclosure provides an LED package structure for increasing heat-dissipating efficiency, including: a substrate unit 1, a conductive unit 2, a heat-dissipating unit 3, a light-emitting unit 4 and a package unit 5.

The substrate unit 1 includes at least one insulating substrate 10, and the insulating substrate 10 can be made of any type of insulating material. For example, the insulating substrate 10 may be is a ceramic substrate that has 92˜98% Al₂O₃ and has been sintered.

The conductive unit 2 can be made of silver material. The conductive unit 2 includes at least two plate-shaped top conductive pads 21 (it means flat conductive pad) disposed on the top surface of the insulating substrate 10, at least two plate-shaped bottom conductive pads 22 (it means flat conductive pad) disposed on the bottom surface of the insulating substrate 10, and a plurality of penetrating conductive posts 23 passing through the insulating substrate 10. The two top conducive pads 21 are respectively electrically connected to the two bottom conductive pads 22 through the penetrating conductive posts 23. For example, the substrate unit 1 includes a plurality of conductive through holes 101 passing through the insulating substrate 10, and the penetrating conductive posts 23 are respectively filled in the conductive through holes 101. In addition, the two top conductive pads 21 and the two bottom conductive pads 22 are substantially symmetrically disposed on two opposite surfaces of the insulating substrate 10.

The heat-dissipating unit 3 includes at least one plate-shaped top heat-dissipating block 31 (it means flat heat-dissipating pad) disposed on the top surface of the insulating substrate 10 and at least one plate-shaped bottom heat-dissipating block 32 (it means flat heat-dissipating pad) disposed on the bottom surface of the insulating substrate 10. For example, the top heat-dissipating block 31 is positioned between the two top conducive pads 21 and the bottom heat-dissipating block 32 is positioned between the two bottom conductive pads 22, and the top heat-dissipating block 31 and the bottom heat-dissipating block 32 are substantially symmetrically disposed on two opposite surfaces of the insulating substrate 10.

The light-emitting unit 4 includes at least one light-emitting element 40 disposed on the top heat-dissipating block 31 and electrically connected between the two top conductive pads 21. For example, the light-emitting element 40 may be an LED chip attached to the top heat-dissipating block 31 through die-attaching glue H or die-attaching piece. The positive electrode and the negative electrode of the light-emitting element 40 can respectively electrically connected to the two top conductive pads 21 through two conductive wires W. Therefore, heat generated by the light-emitting element 40 can be transmitted to external world through the top heat-dissipating block 31, the insulating substrate 10 and the bottom heat-dissipating block 32 in sequence. In other words, the heat generated by the light-emitting element 40 can be transmitted from the top heat-dissipating block 31 to the bottom heat-dissipating block 32, thus the heat-dissipating efficiency of the instant disclosure can be increased effectively.

The package unit 5 includes a package resin 50 disposed on the conductive unit 2 and the heat-dissipating unit 3 to cover the light-emitting element 40. In other words, when the top surface of the insulating substrate 10 is covered with the package resin 50, the conductive unit 2, the heat-dissipating unit 3 and the light-emitting unit 4 are covered with the package resin 50 at the same time. For example, the package resin 50 can be a light-permitting lens made of silicone or epoxy.

Referring to FIG. 2, the second embodiment of the instant disclosure provides an LED package structure for increasing heat-dissipating efficiency, including: a substrate unit 1, a conductive unit 2, a heat-dissipating unit 3, a light-emitting unit 4 and a package unit 5. Comparing FIG. 2 with FIG. 1E, the difference between the second embodiment and the first embodiment is that: in the second embodiment, the heat-dissipating unit 3 includes a plurality of penetrating heat-dissipating layers 33 passing through the insulating substrate 10 and connected between the top heat-dissipating block 31 and the bottom heat-dissipating block 32. In addition, the substrate unit 10 includes a plurality of heat-dissipating through holes 102 passing through the insulating substrate 10, and the penetrating heat-dissipating layers 33 are respectively filled in the heat-dissipating through holes 102.

Therefore, heat generated by the light-emitting element 40 can be transmitted to external world through the top heat-dissipating block 31, the penetrating heat-dissipating layers 33 (of course including the insulating substrate 10) and the bottom heat-dissipating block 32 in sequence. In other words, the heat generated by the light-emitting element 40 can be quickly transmitted from the top heat-dissipating block 31 to the bottom heat-dissipating block 32 through the penetrating heat-dissipating layers 33, thus the heat-dissipating efficiency of the instant disclosure can be increased effectively.

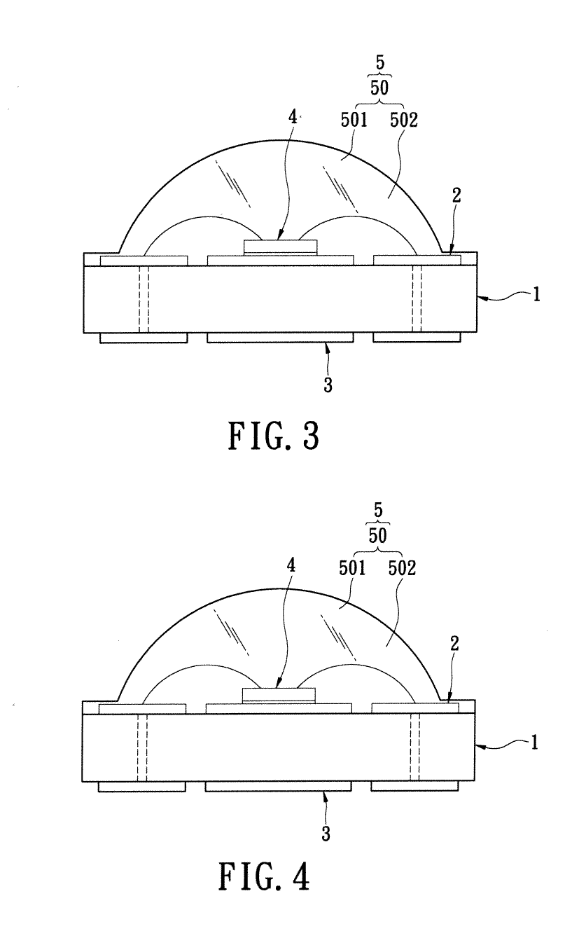

Referring to FIG. 3, the third embodiment of the instant disclosure provides an LED package structure for increasing heat-dissipating efficiency, including: a substrate unit 1, a conductive unit 2, a heat-dissipating unit 3, a light-emitting unit 4 and a package unit 5. Comparing FIG. 3 with FIG. 1E, the difference between the third embodiment and the first embodiment is that: in the third embodiment, the package resin 50 may be a light-permitting lens made mixed by light-permitting resin 501 with phosphor powders 502. For example, the package resin 50 may be a light-permitting lens made mixed by phosphor powders 502 with silicone or epoxy.

Referring to FIG. 4, the fourth embodiment of the instant disclosure provides an LED package structure for increasing heat-dissipating efficiency, including: a substrate unit 1, a conductive unit 2, a heat-dissipating unit 3, a light-emitting unit 4 and a package unit 5. Comparing FIG. 4 with FIG. 3, the difference between the fourth embodiment and the third embodiment is that: in the fourth embodiment, the phosphor powders 502 are deposited and concentrated on the outer surface of the light-emitting element 4 by centrifugal force or deposition method as shown in FIG. 4.

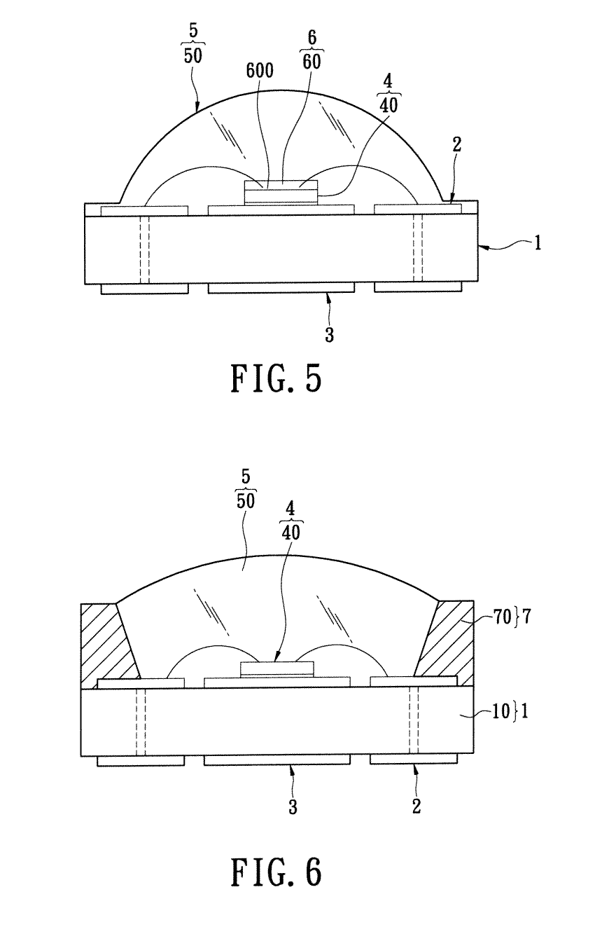

Referring to FIG. 5, the fifth embodiment of the instant disclosure provides an LED package structure for increasing heat-dissipating efficiency, including: a substrate unit 1, a conductive unit 2, a heat-dissipating unit 3, a light-emitting unit 4 and a package unit 5. Comparing FIG. 5 with FIG. 1E, the difference between the fifth embodiment and the first embodiment is that: the fifth embodiment further comprises a phosphor unit 6 that includes a phosphor layer 60 covering the light-emitting element 40, and the phosphor layer 60 includes a plurality of phosphor powders 600 mixed therein and close to the light-emitting element 40. In other words, the phosphor powders 600 can be deposited and concentrated to cover the top surface of the light-emitting element 4, thus light generated by the light-emitting element 40 can pass through the phosphor unit 6 to obtain perfect spectrum conversion.

Referring to FIGS. 1-1, 1-2 and 5, the fifth embodiment provides a method for making the LED package structure. Before the step of S110, the method of the fifth embodiment comprises: forming a phosphor layer 60 mixed with phosphor powders 600 to cover the light-emitting element 40 (S200) by adhesive dripping or spraying; depositing and concentrating the phosphor powders 600 on the light-emitting element 40 by centrifugal force (S202); and then solidifying the phosphor layer 60 for positioning the phosphor layer 60 on the light-emitting element 40 (S204). In addition, the package resin 50 may be a light-permitting lens made of silicone or epoxy, and the phosphor layer 60 is covered by the package resin 50.

Referring to FIG. 6, the sixth embodiment of the instant disclosure provides an LED package structure for increasing heat-dissipating efficiency, including: a substrate unit 1, a conductive unit 2, a heat-dissipating unit 3, a light-emitting unit 4 and a package unit 5. Comparing FIG. 6 with FIG. 1E, the difference between the sixth embodiment and the first embodiment is that: the sixth embodiment further comprises a frame unit 7 that includes an opaque annular frame 70 disposed on the insulating substrate 10 (or on a substrate module M composed of the substrate unit 1, the conductive unit 2 and the heat-dissipating unit 3 as shown in FIG. 1E) and around an external peripheral surface of the package resin 50.

Referring to FIGS. 1-1, 1-2 and 6, the sixth embodiment provides a method for making the LED package structure. Before the step of S110, the method of the sixth embodiment comprises: forming an opaque annular frame 70 on the insulating substrate 10 (or on a substrate module M composed of the substrate unit 1, the conductive unit 2 and the heat-dissipating unit 3 as shown in FIG. 1E) (S300). Hence, when the light-emitting element 40 is covered by the package resin 50, the external peripheral surface of the package resin 50 can be covered by the opaque annular frame 70. Therefore, the light generated by the light-emitting element 40 can be reflected through the inner surface of the opaque annular frame 70 to increase the light-emitting efficiency and the light-gathering capability of the instant disclosure.

In conclusion, heat generated by the light-emitting element can be transmitted to external world through the top heat-dissipating block, the insulating substrate (or the penetrating heat-dissipating layers) and the bottom heat-dissipating block in sequence. In other words, the heat generated by the light-emitting element can be quickly transmitted from the top heat-dissipating block to the bottom heat-dissipating block through the insulating substrate or the penetrating heat-dissipating layers, thus the heat-dissipating efficiency of the instant disclosure can be increased effectively.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. An LED package structure, comprising:
a substrate unit including at least one insulating substrate;
a conductive unit including at least two plate-shaped top conductive pads disposed on the top surface of the at least one insulating substrate, at least two plate-shaped bottom conductive pads disposed on the bottom surface of the at least one insulating substrate, and a plurality of penetrating conductive posts passing through the at least one insulating substrate, wherein the at least two plate-shaped top conducive pads are respectively electrically connected to the at least two plate-shaped bottom conductive pads through the penetrating conductive posts;
a heat-dissipating unit including at least one plate-shaped top heat-dissipating block disposed on the top surface of the at least one insulating substrate and at least one plate-shaped bottom heat-dissipating block disposed on the bottom surface of the at least one insulating substrate;
a light-emitting unit including at least one light-emitting element disposed on the at least one plate-shaped top heat-dissipating block and electrically connected between the at least two plate-shaped top conductive pads; and
a package unit including a package resin disposed on the conductive unit and the heat-dissipating unit to cover the at least one light-emitting element.

2. The LED package structure of claim 1, wherein the at least one insulating substrate is a ceramic substrate that has 92˜98% Al₂O₃ and has been sintered.

3. The LED package structure of claim 1, wherein the substrate unit includes a plurality of conductive through holes passing through the at least one insulating substrate, and the penetrating conductive posts are respectively filled in the conductive through holes.

4. The LED package structure of claim 1, wherein the at least two plate-shaped top conductive pads and the at least two plate-shaped bottom conductive pads are substantially symmetrical.

5. The LED package structure of claim 1, wherein the at least one plate-shaped top heat-dissipating block and the at least one plate-shaped bottom heat-dissipating block are substantially symmetrical.

6. The LED package structure of claim 1, wherein the heat-dissipating unit includes a plurality of penetrating heat-dissipating layers passing through the at least one insulating substrate and connected between the at least one plate-shaped top heat-dissipating block and the at least one plate-shaped bottom heat-dissipating block.

7. The LED package structure of claim 6, wherein the substrate unit includes a plurality of heat-dissipating through holes passing through the at least one insulating substrate, and the penetrating heat-dissipating layers are respectively filled in the heat-dissipating through holes.

8. The LED package structure of claim 1, wherein the at least one light-emitting element is an LED chip attached to the at least one plate-shaped top heat-dissipating block through die-attaching glue.

9. The LED package structure of claim 1, further comprising: a phosphor unit including a phosphor layer covering the light-emitting element, wherein the package resin is a light-permitting lens made of silicone or epoxy.

10. The LED package structure of claim 1, wherein the package resin is a light-permitting lens made mixed by phosphor powders with silicone or epoxy.

11. The LED package structure of claim 1, further comprising: a frame unit including an opaque annular frame disposed on the at least one insulating substrate and around an external peripheral surface of the package resin.

12. An LED package structure, comprising:
a substrate unit including at least one insulating substrate;
a conductive unit including at least two top conductive pads disposed on the top surface of the at least one insulating substrate, at least two bottom conductive pads disposed on the bottom surface of the at least one insulating substrate, and a plurality of penetrating conductive posts passing through the at least one insulating substrate, wherein the at least two top conducive pads are respectively electrically connected to the at least two bottom conductive pads through the penetrating conductive posts;
a heat-dissipating unit including at least one top heat-dissipating block disposed on the top surface of the at least one insulating substrate and at least one bottom heat-dissipating block disposed on the bottom surface of the at least one insulating substrate;
a light-emitting unit including at least one light-emitting element disposed on the at least one top heat-dissipating block and electrically connected between the at least two top conductive pads;
a package unit including a package resin disposed on the conductive unit and the heat-dissipating unit to cover the at least one light-emitting element; and
a frame unit including an opaque annular frame disposed on the at least one insulating substrate and around an external peripheral surface of the package resin.

13. A method of making an LED package structure, comprising the steps of:
(a) providing a substrate module including a substrate unit, a conductive unit and a heat-dissipating unit, wherein the substrate unit includes at least one insulating substrate, the conductive unit includes at least two top conductive pads disposed on the top surface of the at least one insulating substrate, at least two bottom conductive pads disposed on the bottom surface of the at least one insulating substrate and a plurality of penetrating conductive posts passing through the at least one insulating substrate, the at least two top conducive pads are respectively electrically connected to the at least two bottom conductive pads through the penetrating conductive posts, and the heat-dissipating unit includes at least one top heat-dissipating block disposed on the top surface of the at least one insulating substrate and at least one bottom heat-dissipating block disposed on the bottom surface of the at least one insulating substrate;
(b) attaching at least one light-emitting element to the at least one top heat-dissipating block through die-attaching glue;
(c) solidifying the die-attaching glue to position the at least one light-emitting element on the at least one top heat-dissipating block;
(d) cleaning the outer surface of the at least one light-emitting element and the outer surface of the at least two top conductive pads by plasma;
(e) electrically connecting the at least one light-emitting element between the at least two top conductive pads; and
(f) forming a package resin to cover the at least one light-emitting element.

14. The method of claim 13, wherein the substrate unit includes a plurality of conductive through holes passing through the at least one insulating substrate, and the penetrating conductive posts are respectively filled in the conductive through holes.

15. The method of claim 13, wherein the heat-dissipating unit includes a plurality of penetrating heat-dissipating layers passing through the at least one insulating substrate and connected between the at least one top heat-dissipating block and the at least one bottom heat-dissipating block, the substrate unit includes a plurality of heat-dissipating through holes passing through the at least one insulating substrate, and the penetrating heat-dissipating layers are respectively filled in the heat-dissipating through holes.

16. The method of claim 13, further comprises sequentially washing and baking the substrate module and the at least one light-emitting element before the step of (b).

17. The method of claim 13, further comprising: pre-curing the substrate module and the at least one light-emitting element to remove redundant moisture after the step of (e).

18. The method of claim 13, wherein before the step of (f), the method further comprising:
forming a phosphor layer mixed with phosphor powders to cover the at least one light-emitting element;
depositing and concentrating the phosphor powders on the at least one light-emitting element by centrifugal force; and
solidifying the phosphor layer for positioning the phosphor layer on the at least one light-emitting element, wherein the package resin is a light-permitting lens made of silicone or epoxy.

19. The method of claim 13, wherein the package resin is a light-permitting lens made mixed by phosphor powders with silicone or epoxy.

20. The method of claim 13, further comprising: forming an opaque annular frame on the at least one insulating substrate and around an external peripheral surface of the package resin before the step of (f).
